(19) United States
(12) Patent Application Publication
(10) Pub. No.: US 2026/0360327 A1
(43) Pub. Date: Nov. 12, 2026

(54) DISPLAY PANEL AND SPLICED DISPLAY DEVICE

(71) Applicant: AUO Corporation, Hsinchu City (TW)

(72) Inventors: Chia-Jung Wu, Hsinchu City (TW); Ti-Kuei Yu, Hsinchu City (TW); Ya-Ling Hsu, Hsinchu City (TW)

(73) Assignee: AUO Corporation, Hsinchu City (TW)

(21) Appl. No.: 19/321,293

(22) Filed: Sep. 7, 2025

(30) Foreign Application Priority Data
May 12, 2025 (TW) 114117729

(51) Int. Cl. G09G 3/36; G02F 1/1339; G02F 1/1362; G09G 3/32

(52) U.S. Cl. CPC G09G 3/3677; G02F 1/1339; G02F 1/136286; G09G 3/32; G09G 2300/026; G09G 2320/0233

(57) ABSTRACT

A display panel includes a substrate, liquid crystal pixels, light-emitting diode pixels, first data lines and a multiplexer. The substrate includes a liquid crystal display area and a light-emitting diode display region. The liquid crystal pixels are arrayed above the liquid crystal display region. The light-emitting diode pixels are arrayed above the light-emitting diode display region. The first data lines are located above the substrate and extend from above the light-emitting diode display area to above the liquid crystal display area. One of the first data lines is electrically connected to corresponding ones of the liquid crystal pixels and at least one of the light-emitting diode pixels. Corresponding ones of the liquid crystal pixels and at least one of the light-emitting diode pixels are arranged along a first direction. The multiplexer is located above the substrate and connected to the one of the first data lines.

### CROSS-REFERENCE TO RELATED APPLICATION

This application claims the priority benefit of Taiwan application serial no. 114117729, filed on May 12, 2025. The entirety of the above-mentioned patent application is hereby incorporated by reference herein and made a part of this specification.

### BACKGROUND

### Technical Field

The present invention relates to a display panel and a spliced display device.

### Related Art

A spliced display device is composed of display panels, these display panels are arranged and bonded together to form a larger-sized display screen. Such devices are commonly used in applications such as advertising walls and digital signage, presenting complete images through the coordinated operation of a plurality of display panels.

However, gaps between display panels may cause image discontinuity problems, affecting screen consistency. These gaps may cause brightness differences, alignment errors, or screen breaks, thereby reducing the overall viewing experience.

### SUMMARY

The present invention provides a display panel having the advantage of a narrow bezel.

The present invention provides a spliced display device that may improve the problem of image discontinuity appearing at the boundaries of display panels.

At least one embodiment of the present invention provides a display panel including a substrate, a plurality of liquid crystal pixels, a plurality of light emitting diode (LED) pixels, a plurality of first data lines, and a multiplexer. The substrate includes a liquid crystal display region and a LED display region, the LED display region is located on at least one side of the liquid crystal display region. The liquid crystal pixels are arrayed above the liquid crystal display region. The LED pixels are arrayed above the LED display region. The first data lines are located above the substrate and extend from above the LED display region to above the liquid crystal display region. One of the first data lines is electrically connected to corresponding multiple ones of the liquid crystal pixels and at least one of the LED pixels. The corresponding multiple ones of the liquid crystal pixels and the at least one of the LED pixels are arranged along a first direction. The multiplexer is located above the substrate and connected to the one of the first data lines.

At least one embodiment of the present invention provides a spliced display device including a plurality of display panels spliced together.

Based on the above, by providing the LED display region on at least one side of the liquid crystal display region, the area outside the liquid crystal display region may also have the function of displaying images, thereby achieving the advantage of a narrow bezel. In addition, after tiling display panels together, the LED display region is included between the liquid crystal display regions of adjacent display panels, therefore, the problem of image discontinuity appearing at the boundaries of display panels may be improved.

### BRIEF DESCRIPTION OF THE DRAWINGS

FIG. 1A is a top view schematic diagram of a spliced display device according to an embodiment of the present invention.

FIG. 1B is a cross-sectional schematic diagram of one of the display panels in the spliced display device of FIG. 1A.

FIG. 2 is a partial top view schematic diagram of a display panel according to an embodiment of the present invention.

FIG. 3 is a partial top view schematic diagram of a display panel according to an embodiment of the present invention.

FIG. 4A is a partial top view schematic diagram of the liquid crystal pixel of the display panel of FIG. 3.

FIG. 4B is a cross-sectional schematic diagram along line A-A′ of FIG. 4A.

FIG. 5A is a partial top view schematic diagram of a display panel according to an embodiment of the present invention.

FIG. 5B is a top view schematic diagram of a chip on film package according to an embodiment of the present invention.

FIG. 6A is a partial top view schematic diagram of a multiplexer according to an embodiment of the present invention.

FIG. 6B is a partial top view schematic diagram of a multiplexer according to an embodiment of the present invention.

FIG. 7 is a timing diagram of various signals for driving a display panel according to an embodiment of the present invention.

FIG. 8 is a top view schematic diagram of a spliced display device according to an embodiment of the present invention.

### DESCRIPTION OF THE EMBODIMENTS

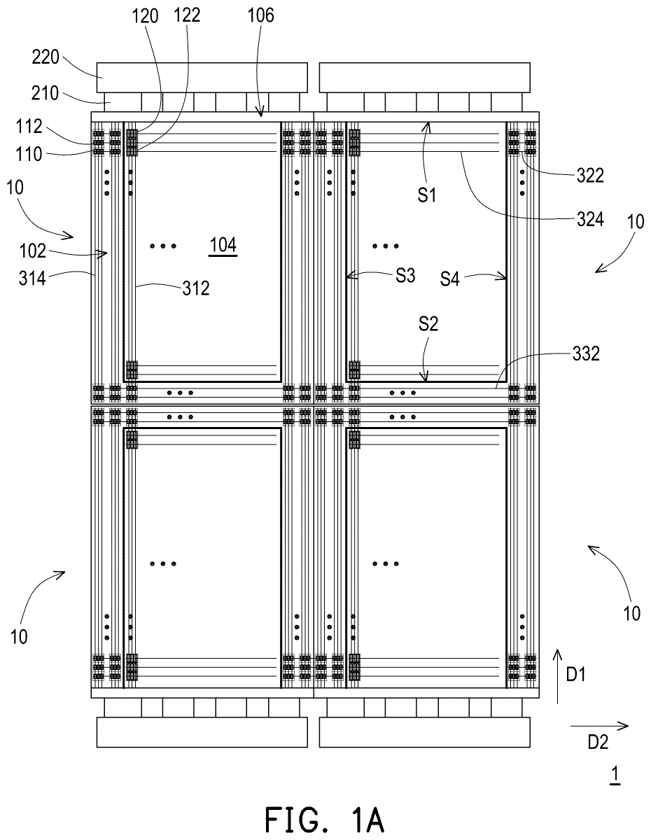

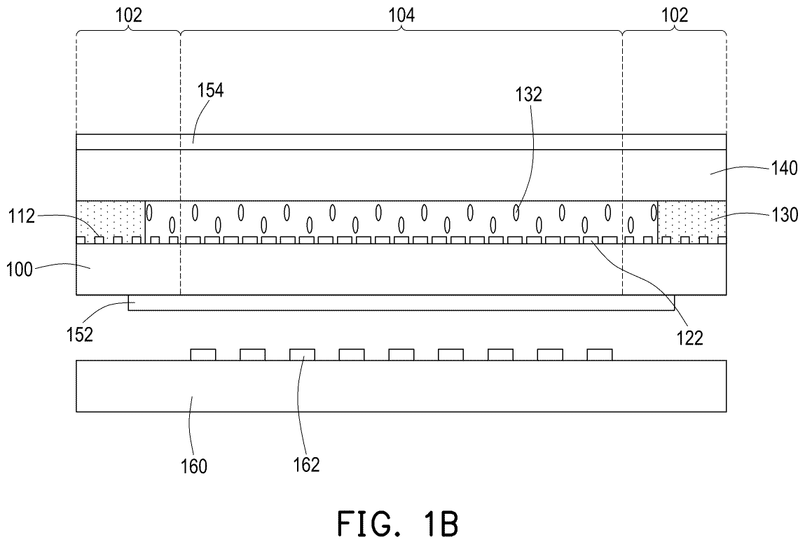

FIG. 1A is a schematic diagram of a spliced display device 1 according to an embodiment of the present invention. FIG. 1B is a cross-sectional schematic diagram of one of the display panels 10 in the spliced display device of FIG. 1A. Referring to FIG. 1A and FIG. 1B, the spliced display device 1 includes display panels 10 tiled together. In the embodiment of FIG. 1A, the spliced display device 1 includes 4 display panels 10 as an example, but the present disclosure is not limited thereto. According to actual requirements, the spliced display device 1 may include more or fewer display panels 10.

Referring to FIG. 1A and FIG. 1B, each display panel 10 includes a first substrate 100, multiple liquid crystal pixels 120, multiple light-emitting diode (LED) pixels 110, a sealant 130, a liquid crystal layer 132, a second substrate 140, a first polarizer 152, a second polarizer 154, and a backlight module 160.

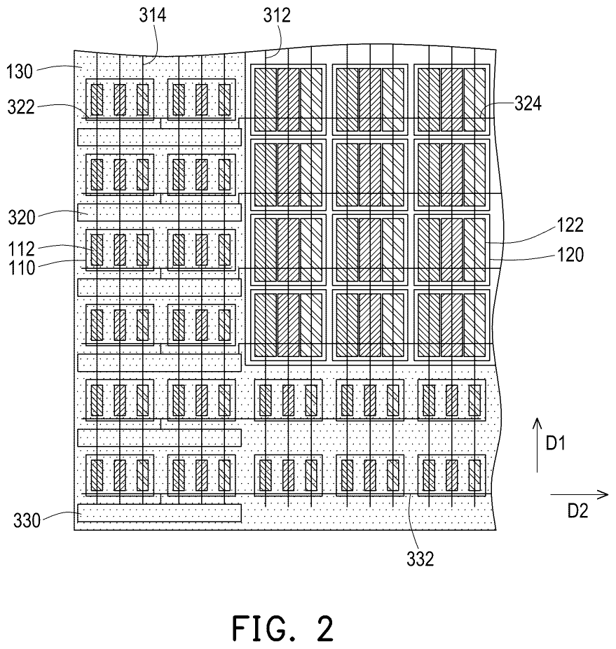

The LED pixels 110 and the liquid crystal pixels 120 are respectively arrayed above the LED display region 102 and the liquid crystal display region 104 of the first substrate 100. FIG. 1B shows the LEDs 112 in the LED pixels 110 and the pixel electrodes 122 in the liquid crystal pixels 120, and omits other components of the LED pixels 110 and the liquid crystal pixels 120 (for example, pixel control circuits including thin film transistors). In some embodiments, each of the LED pixels 110 and the liquid crystal pixels 120 includes a red sub-pixel, a green sub-pixel, and a blue sub-pixel, and the LEDs 112 and pixel electrodes 122 corresponding to sub-pixels of different colors are represented by different fill patterns in the figures, as shown in FIG. 2.

The sealant 130 is located above the LED display region 102 and surrounds the liquid crystal layer 132 located above the liquid crystal display region 104. The sealant 130 covers the LEDs 112 of the LED pixels 110. The liquid crystal layer 132 is located above the pixel electrodes 122 of the liquid crystal pixels 120 and portions of the LED pixels 110. In some embodiments, the liquid crystal layer 132 may be operated using twisted nematic (TN) liquid crystal technology, vertical alignment (VA) liquid crystal technology, fringe field switching (FFS) liquid crystal technology, in-plane switching (IPS) liquid crystal technology, advanced hyper-viewing angle (AHVA) liquid crystal technology, or other suitable liquid crystal technology.

The second substrate 140 overlaps the first substrate 100, and the sealant 130 and the liquid crystal layer 132 are located between the first substrate 100 and the second substrate 140.

The first polarizer 152 and the second polarizer 154 are respectively located on the first substrate 100 and the second substrate 140, and at least overlap the liquid crystal display region 104. In this embodiment, the first polarizer 152 and the second polarizer 154 are respectively located on the outer sides of the first substrate 100 and the second substrate 140, but the present disclosure is not limited thereto. In other embodiments, the first polarizer 152 and/or the second polarizer 154 are located between the first substrate 100 and the second substrate 140.

The backlight module 160 overlaps the first substrate 100, and the light source 162 of the backlight module 160 is configured to provide light to the liquid crystal display region 104. In the embodiment of FIG. 1B, the backlight module 160 is a direct-lit backlight module, but the present disclosure is not limited thereto. In other embodiments, the backlight module 160 is an edge-lit backlight module or other types of backlight modules.

Referring to FIG. 1A, each display panel 10 further includes a chip on film package 210 and a system circuit board 220. The chip on film package 210 is bonded to bonding pads (omitted in FIG. 1A) on the bonding region 106 of the first substrate 100, and is used to provide various operation signals to the LED pixels 110 and the liquid crystal pixels 120. The system circuit board 220 is electrically connected to the chip on film package 210.

In this embodiment, the bonding region 106 is located on the first side S1 of the liquid crystal display region 104, and the LED display region 102 is located on at least one of the second side S2, the third side S3, and the fourth side S4 of the liquid crystal display region 104. In this embodiment, the LED display region 102, for example, is located on three sides of the liquid crystal display region 104.

Multiple first data lines 312 (omitted in FIG. 1B) are located above the first substrate 100, and extend from above the LED display region 102 to above the liquid crystal display region 104. Each first data line 312 is electrically connected to corresponding multiple liquid crystal pixels 120 and at least one LED pixel 110 arranged along the first direction D1. In this embodiment, each first data line 312 extends from above the LED display region 102 across the second side S2 and the first side S1 of the liquid crystal display region 104, and extends into the region above the bonding region 106.

A multiplexer (omitted in FIG. 1A and FIG. 1B) is located above the bonding region 106 of the first substrate 100, and is connected to the first data lines 312. The multiplexer is configured to enable the data signals on the first data lines 312 to switch between data signals corresponding to the LED pixels 110 and data signals corresponding to the liquid crystal pixels 120. Therefore, the same first data line 312 may be used to operate two different pixel structures: the LED pixels 110 and the liquid crystal pixels 120.

Multiple second data lines 314 (omitted in FIG. 1B) are located above the first substrate 100. The second data lines 314 are located above the LED display region 102 and do not overlap the liquid crystal display region 104. The second data lines 314 extend along the first direction D1, and extend along the third side S3 and the fourth side S4 of the liquid crystal display region 104. The second data lines 314 are electrically connected to corresponding multiple LED pixels 110. The second data lines 314 extend into the region above the bonding region 106.

Multiple first scan lines 322 (omitted in FIG. 1B) are located above the LED display region 102, and extend along the second direction D2. Each first scan line 322 is electrically connected to corresponding at least one LED pixel 110 to control the pixel control circuit of the corresponding LED pixel 110. The first direction D1 is substantially perpendicular to the second direction D2.

Multiple second scan lines 324 (omitted in FIG. 1B) are located above the liquid crystal display region 104, and extend along the second direction D2. Each second scan line 324 is electrically connected to corresponding multiple liquid crystal pixels 120 to control the pixel control circuits of the liquid crystal pixels 120.

One or multiple third scan lines 332 (omitted in FIG. 1B) are located above the LED display region 102, and do not overlap the liquid crystal display region 104. The third scan lines 332 extend along the second side S2 of the liquid crystal display region 104, and extend along the second direction D2. Each third scan line 332 is electrically connected to corresponding multiple LED pixels 110 arranged along the second direction D2 to control the pixel control circuits of the corresponding LED pixels 110.

In some embodiments, the first scan lines 322, the second scan lines 324, and the third scan lines 332 are controlled through multiple gate driver circuits formed above the first substrate 100. For example, referring to FIG. 2, the first gate driver circuit 320 and the second gate driver circuit 330 are located above the LED display region 102, and at least partially overlap the sealant 130, wherein the first gate driver circuit 320 and the second gate driver circuit 330 may also be referred to as gate driver-on-array (GOA). The first scan line 322 extends along the second direction D2, and electrically connect the first gate driver circuit 320 to corresponding at least one LED pixel 110. The second scan line 324 electrically connects the first gate driver circuit 320 to corresponding multiple ones among the liquid crystal pixels 120 arranged along the second direction D2. In this embodiment, the liquid crystal pixels 120 and the LED pixels 110 electrically connected to the same first gate driver circuit 320 are arranged along the second direction D2. The third scan line 332 extends along the second direction D2, and electrically connect the second gate driver circuit 330 to multiple ones among the LED pixels 110 arranged along the second direction D2. In some embodiments, the length of the third scan lines 332 is greater than the length of the first scan lines 322 and the length of the second scan lines 324.

In other embodiments, no gate driver circuit is formed above the LED display region 102 of the first substrate 100. Instead, the chip on film package 210 includes gate driver circuits, and the first scan lines 322, the second scan lines 324, and the third scan lines 332 are electrically connected to the gate driver circuits in the chip on film package 210 (refer to FIG. 1A).

In this embodiment, by providing the LED display region 102 on at least one side of the liquid crystal display region 104, the area outside the liquid crystal display region 104 may also have the function of displaying images, thereby achieving the advantage of narrow bezels. Furthermore, after multiple display panels 10 are tiled together, the LED display region 102 is included between the liquid crystal display regions 104 of adjacent display panels 10, therefore, the advantage of seamless tiling may be obtained, improving the problem of image discontinuity appearing at the boundaries of the display panels 10.

Additionally, since the manufacturing cost of liquid crystal pixels is lower than the manufacturing cost of LED pixels, the display panel of the present disclosure uses liquid crystal pixels and LED pixels together, which may achieve the purpose of cost reduction.

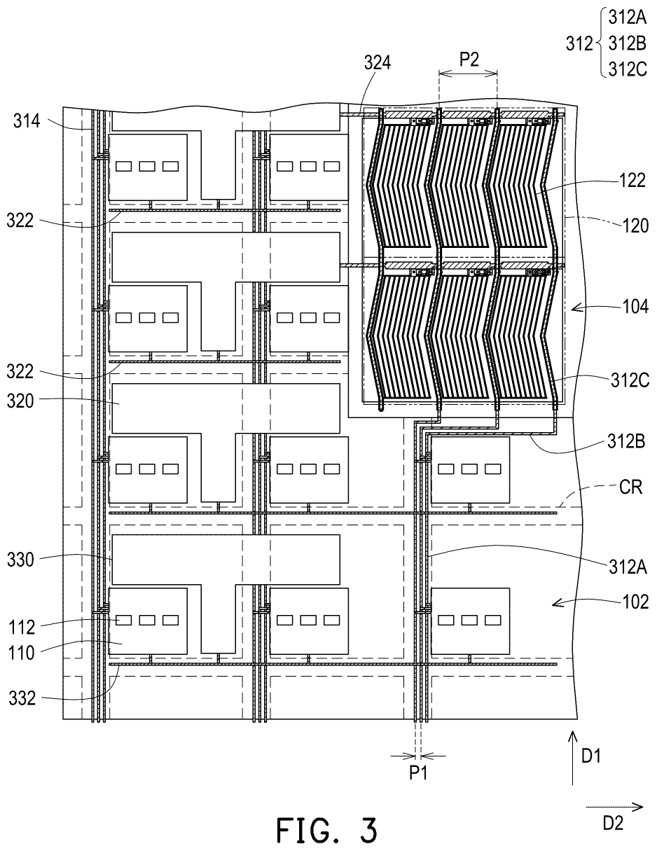

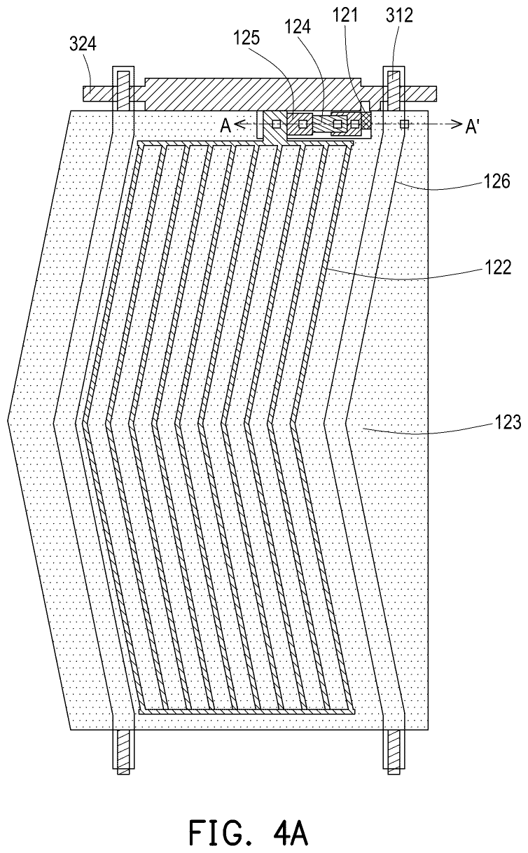

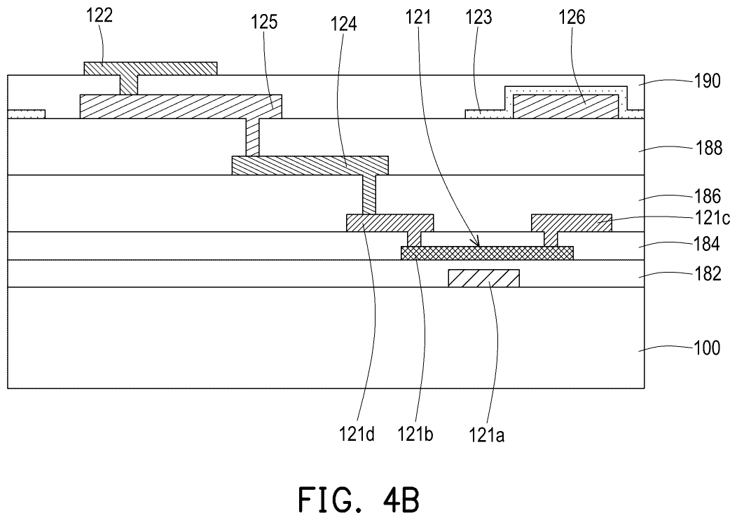

FIG. 3 is a partial top view schematic diagram of a display panel according to an embodiment of the present invention. FIG. 4A is a partial top view schematic diagram of a liquid crystal pixel of the display panel of FIG. 3. FIG. 4B is a cross-sectional schematic diagram along line A-A′ of FIG. 4A. Referring to FIG. 3, in this embodiment, the LED display region 102 includes a circuit layout region CR. The circuit layout region CR is, for example, grid-shaped, and includes longitudinal portions extending along the first direction D1 and lateral portions extending along the second direction D2. The second data lines 314, the first scan lines 322, and the third scan lines 332 are disposed on the circuit layout region CR. Although FIG. 3 does not show, in some embodiments, the circuit layout region CR further includes other signal lines, such as ground signal lines, light emission control signal lines, reset signal lines, and other various signal lines for operating the LED pixels 110.

In this embodiment, the first data line 312 includes a first conductive line portion 312A, a transition portion 312B, and a second conductive line portion 312C. The first conductive line portion 312A is connected to at least one LED pixel 110. The second conductive line portion 312C is connected to corresponding multiple liquid crystal pixels 120. The transition portion 312B connects the first conductive line portion 312A to the second conductive line portion 312C. The extending direction of the transition portion 312B (for example, the second direction D2) is different from the extending direction of the first conductive line portion 312A and the extending direction of the second conductive line portion 312C (for example, the first direction D1).

In some embodiments, one of the first data lines 312 and another one of the first data lines 312 adjacent thereto have a first pitch P1 above the LED display region 102. The first pitch P1 may also be referred to as the pitch between the first conductive line portions 312A connected to the same LED pixel 110. One of the first data lines 312 and another one of the first data lines 312 adjacent thereto have a second pitch P2 above the liquid crystal display region 104. The second pitch P2 may also be referred to as the pitch between the second conductive line portions 312C connected to the same liquid crystal pixel 120. In some embodiments, the second pitch P2 is different from the first pitch P1, for example, the second pitch P2 is greater than the first pitch P1.

In some embodiments, the second conductive line portion 312C has a zigzag shape, and the first conductive line portion 312A has a straight line shape, but the present disclosure is not limited thereto. In other embodiments, both the second conductive line portion 312C and the first conductive line portion 312A have straight line shapes.

FIG. 4A is a partial top view schematic diagram of the liquid crystal pixel 120 of the display panel of FIG. 3. Specifically, FIG. 4A shows one sub-pixel of the liquid crystal pixel 120. FIG. 4B is a cross-sectional schematic diagram along line A-A′ of FIG. 4A. Referring to FIG. 4A and FIG. 4B, the liquid crystal pixel 120 includes a thin film transistor 121, a pixel electrode 122, and a common electrode 123.

The thin film transistor 121 includes a gate 121a, a channel layer 121b, a first source/drain 121c, and a second source/drain 121d. The gate 121a is located on the first substrate 100 and is electrically connected to the second scan line 324. The dielectric layer 182 is located on the first substrate 100 and covers the gate 121a. The channel layer 121b is located on the dielectric layer 182 and overlaps the gate 121a. The dielectric layer 184 is located on the channel layer 121b. The first source/drain 121c and the second source/drain 121d are located on the dielectric layer 184 and are electrically connected to the channel layer 121b. The first source/drain 121c is electrically connected to the first data line 312.

The dielectric layer 186 is located on the first source/drain 121c and the second source/drain 121d. The first transition electrode 124 is located on the dielectric layer 186 and is electrically connected to the second source/drain 121d. The dielectric layer 188 is located on the first transition electrode 124. The second transition electrode 125 and the common signal line 126 are located on the dielectric layer 188. The second transition electrode 125 is electrically connected to the first transition electrode 124. The common electrode 123 is formed on the common signal line 126. In some embodiments, the common electrode 123 includes a transparent conductive material. The dielectric layer 190 is located on the common electrode 123. The pixel electrode 122 is located on the dielectric layer 190.

In some embodiments, the dielectric layers 182, 184, 186, 188, 190 each have a single-layer or multi-layer structure. In some embodiments, the dielectric layers 186, 188 include organic material layers and are suitable for ultra high aperture (UHA) display panel technology.

In the embodiments of FIG. 4A and FIG. 4B, the thin film transistor 121 is a bottom gate type thin film transistor, but the present disclosure is not limited thereto. In other embodiments, the thin film transistor 121 is a top gate type thin film transistor, a dual gate type thin film transistor, or other types of thin film transistors.

In the present embodiment, the common signal line 126 and the common electrode 123 are formed on the first substrate 100, but the present disclosure is not limited thereto. In other embodiments, the common electrode 123 is formed on the second substrate 140 (please refer to FIG. 1B).

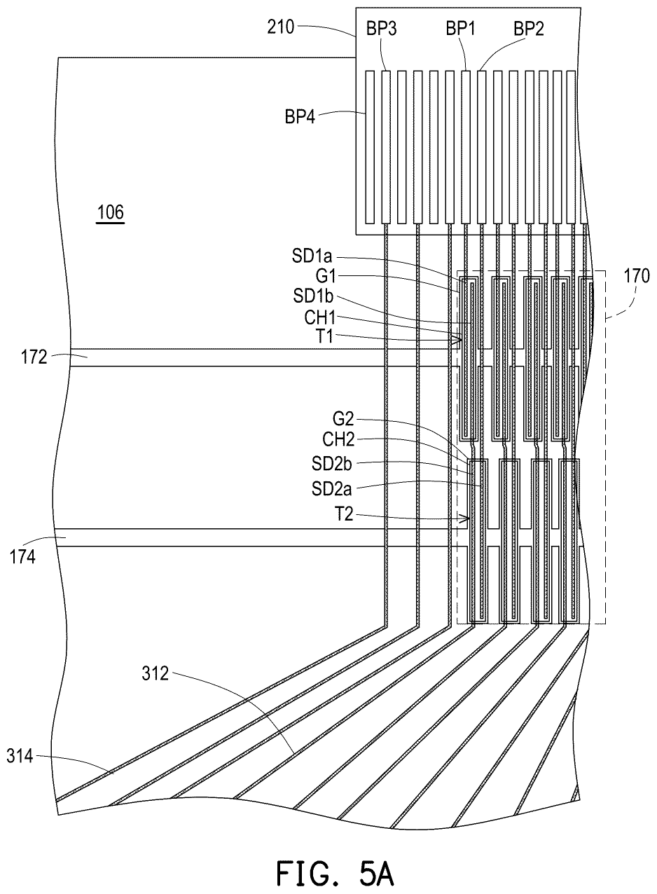

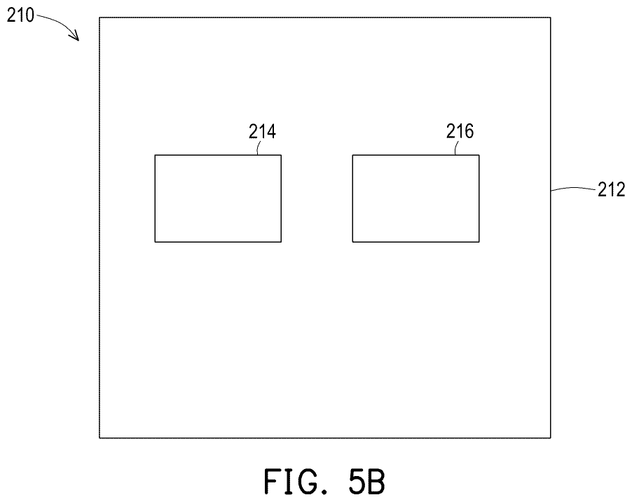

FIG. 5A is a partial top view schematic diagram of a display panel according to an embodiment of the present invention. FIG. 5B is a top view schematic diagram of a chip on film package according to an embodiment of the present invention. For example, FIG. 5A is a partial enlarged schematic diagram of the bonding region 106 of the display panel 10 of FIG. 1A, and FIG. 5B is an enlarged schematic diagram of the chip on film package 210 of FIG. 1A. Referring to FIG. 5A, the multiplexer 170 is located above the bonding region 106 and includes a first transistor T1 and a second transistor T2.

The first transistor T1 includes a first source/drain SD1a, a second source/drain SD1b, a first channel layer CH1, and a first gate G1. The second transistor T2 includes a first source/drain SD2a, a second source/drain SD2b, a second channel layer CH2, and a second gate G2. In some embodiments, the materials of the first channel layer CH1 and the second channel layer CH2 include amorphous silicon, polycrystalline silicon, microcrystalline silicon, single crystal silicon, organic semiconductor materials, oxide semiconductor materials (for example: indium zinc oxide, indium gallium zinc oxide or other suitable materials, or combinations of the above materials) or other suitable materials or combinations of the above materials.

The first gate G1 of the first transistor T1 and the second gate G2 of the second transistor T2 are electrically connected to the first gate control line 172 and the second gate control line 174, respectively. In the present embodiment, one first gate control line 172 is electrically connected to the first gates G1 of multiple first transistors T1, and one second gate control line 174 is electrically connected to the second gates G2 of multiple second transistors T2.

The first source/drain SDla of the first transistor T1 and the first source/drain SD2a of the second transistor T2 are electrically connected to the first bonding pad BP1 and the second bonding pad BP2, respectively, and are electrically connected to the chip on film package 210 through the first bonding pad BP1 and the second bonding pad BP2. The second source/drain SD1b of the first transistor T1 and the second source/drain SD2b of the second transistor T2 are both electrically connected to the corresponding first data line 312. In the present embodiment, each first data line 312 is electrically connected to one first transistor T1 and one second transistor T2.

Referring to FIGS. 5A and 5B, the chip on film package 210 is bonded to multiple first bonding pads BP1, multiple second bonding pads BP2, multiple third bonding pads BP3, and multiple fourth bonding pads BP4. The chip on film package 210 includes a circuit board 212, an LED pixel driver circuit 214, and a liquid crystal pixel driver circuit 216. The LED pixel driver circuit 214 and the liquid crystal pixel driver circuit 216 may be two separate chips, or may be integrated in the same chip. In some embodiments, the LED pixel driver circuit 214 and the liquid crystal pixel driver circuit 216 each have different gamma correction curves.

In the present embodiment, by disposing the LED pixel driver circuit 214 and the liquid crystal pixel driver circuit 216 in the same chip on film package 210, the number of chip on film packages required may be reduced, thereby reducing the bezel width. Furthermore, through the arrangement of the multiplexer 170, the LED pixel driver circuit 214 and the liquid crystal pixel driver circuit 216 may share the first data line 312, thereby reducing the total number of data lines, reducing the demand for crossover design of data lines, and thus avoiding problems caused by crossover design (such as signal line damage). Additionally, reducing the number of data lines may also increase the aperture ratio of the display region.

The LED pixel driver circuit 214 and the liquid crystal pixel driver circuit 216 are located on the circuit board 212. The LED pixel driver circuit 214 is electrically connected to the first source/drain SDla of the first transistor T1 of the multiplexer 170 through the circuit board 212 and the first bonding pad BP1, and the liquid crystal pixel driver circuit 216 is electrically connected to the first source/drain SD2a of the second transistor T2 of the multiplexer 170 through the circuit board 212 and the second bonding pad BP2. The multiplexer 170 is configured to switch the first data line 312 between receiving signals output from the LED pixel driver circuit 214 and receiving signals output from the liquid crystal pixel driver circuit 216.

In the present embodiment, the third bonding pad BP3 and the fourth bonding pad BP4 are electrically connected to the LED pixel driver circuit 214 and the liquid crystal pixel driver circuit 216, respectively, wherein the third bonding pad BP3 is electrically connected to the second data line 314, and the fourth bonding pad BP4 is not connected to any data line.

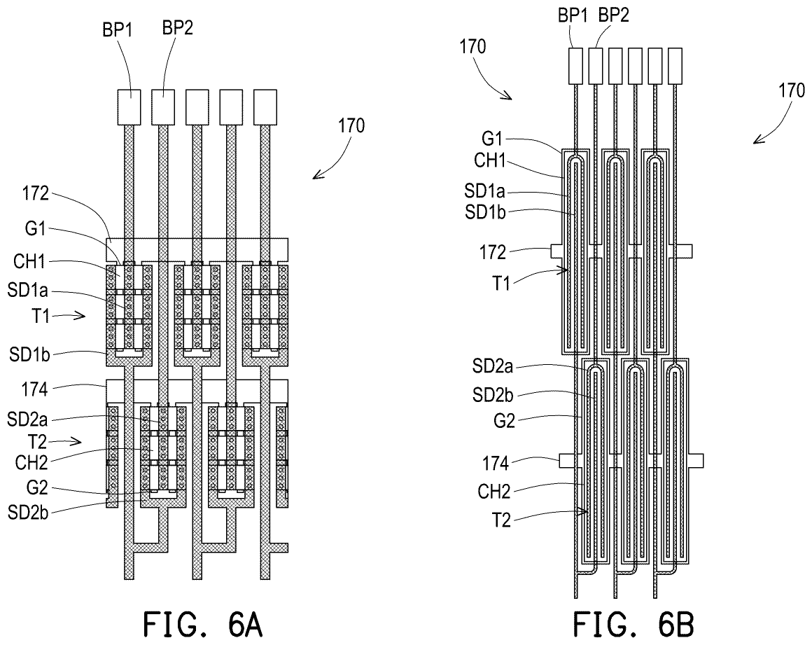

It should be noted that the structures of the first transistor T1 and the second transistor T2 shown in FIG. 5A are merely illustrative and are not intended to limit the multiplexer of the present disclosure. Specifically, the first transistor T1 and the second transistor T2 may also have structures as shown in FIG. 6A or FIG. 6B.

In the multiplexer 170 of FIG. 6A, the first transistor T1 includes multiple first semiconductor structures CHI separated from each other. The first gate G1, the first source/drain SDla, and the second source/drain SD1b of the first transistor T1 overlap the first semiconductor structures CH1, and the first source/drain SDla extends from above the first semiconductor structures CH1 to the first bonding pad BP1. The second transistor T2 includes multiple second semiconductor structures CH2 separated from each other. The second gate G2, the first source/drain SD2a, and the second source/drain SD2b of the second transistor T2 overlap the second semiconductor structures CH2, and the first source/drain SD2a extends from above the second semiconductor structures CH2 to the second bonding pad BP2.

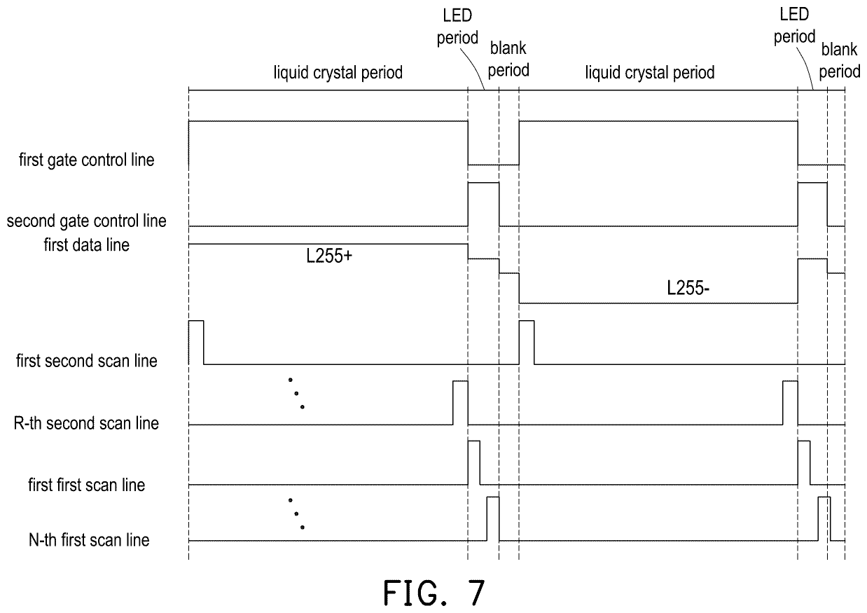

FIG. 7 is a timing diagram of various signals for driving a display panel according to an embodiment of the present invention. Referring to FIG. 7, when displaying images, each frame includes a liquid crystal period, an LED period, and a blank period.

In the liquid crystal period, the second transistor T2 is turned on through the first gate control line 172 (refer to FIG. 5A), while the first transistor T1 is turned off (refer to FIG. 5A). For example, as shown in FIG. 7, the first gate control line is at high potential, while the second gate control line is at low potential. In the liquid crystal period, the liquid crystal pixel driver circuit 216 (refer to FIG. 5B) in the chip on film package 210 may provide signals to the first data line 312 through the second bonding pad BP2 (refer to FIG. 5A) and the second transistor T2.

In the liquid crystal period, the second scan lines 324 on the liquid crystal display region 104 are sequentially scanned (refer to FIG. 2). For example, scanning from the first second scan line 324 to the R-th second scan line 324, where R is an integer greater than 1.

Next, the LED period is entered. In the LED period, the first transistor T1 is turned on through the second gate control line 174 (refer to FIG. 5A), while the second transistor T2 is turned off (refer to FIG. 5A). For example, as shown in FIG. 7, the second gate control line is at high potential, while the first gate control line is at low potential. In the LED period, the LED pixel driver circuit 214 (refer to FIG. 5B) in the chip on film package 210 may provide signals to the first data line 312 through the first bonding pad BP1 (refer to FIG. 5A) and the first transistor T1.

In the LED period, the first scan lines 322 on the LED display region 102 are sequentially scanned (refer to FIG. 2). For example, scanning from the first first scan line 322 to the N-th first scan line 322, where N is an integer greater than 1.

In some embodiments, the voltage polarity applied across the liquid crystal layer must be inverted at regular intervals to avoid polarization of the liquid crystal material that may cause permanent damage, and also to avoid image sticking. For example, in some liquid crystal periods, positive polarity brightness signal (shown as L255+ in FIG. 7) are provided to the first data line, while in other liquid crystal periods, negative polarity brightness signal (shown as L255− in FIG. 7) are provided to the first data line. Additionally, in some embodiments, the LED does not need to operate with polarity inversion.

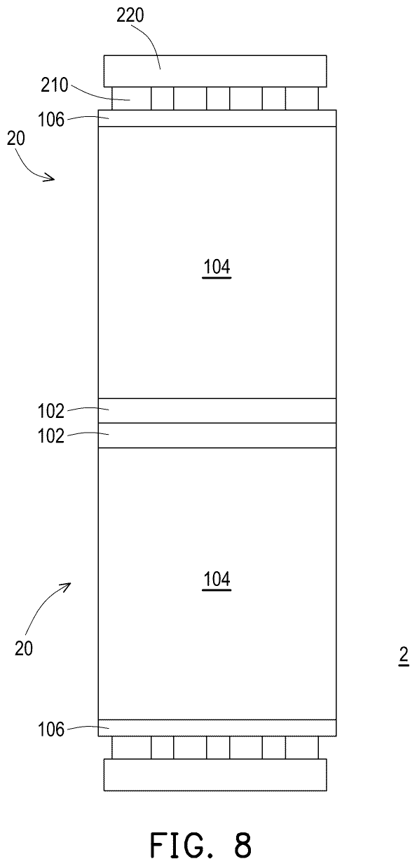

FIG. 8 is a top view of a tiled display device 2 according to an embodiment of the present invention. It must be noted that the embodiment of FIG. 8 adopts the component reference numerals and partial content of the embodiment of FIG. 1A, wherein the same or similar reference numerals are used to represent the same or similar components, and descriptions of the same technical content are omitted. For descriptions of the omitted portions, reference may be made to the aforementioned embodiments, which will not be repeated here. In the display device 2 of FIG. 8, the LED display region 102 of each display panel 20 is located on a side of the liquid crystal display region 104 opposite to the bonding region 106.

In summary, the present invention may achieve the advantage of narrow bezels by providing the LED display region on at least one side of the liquid crystal display region, which enables the area outside the liquid crystal display region to also have the function of displaying images. Furthermore, after multiple display panels are tiled together, the LED display region is included between the liquid crystal display regions of adjacent display panels, therefore, the problem of image discontinuity appearing at the boundaries of the display panels may be improved.

1. A display panel, comprising:
a substrate comprising a liquid crystal display region and a light-emitting diode display region, wherein the light-emitting diode display region is located on at least one side of the liquid crystal display region;
a plurality of liquid crystal pixels arrayed above the liquid crystal display region;
a plurality of light-emitting diode pixels arrayed above the light-emitting diode display region;
a plurality of first data lines located above the substrate and extending from above the light-emitting diode display region to above the liquid crystal display region, wherein one of the plurality of first data lines is electrically connected to corresponding ones of the liquid crystal pixels and at least one of the light-emitting diode pixels, wherein the corresponding ones of the plurality of liquid crystal pixels and the at least one of the plurality of light-emitting diode pixels are arranged along a first direction;
a multiplexer located above the substrate and connected to the one of the plurality of first data lines;
a liquid crystal layer located above the liquid crystal display region; and
a sealant located above the light-emitting diode display region, and surrounding the liquid crystal layer, wherein the sealant covers light-emitting diodes of the plurality of light-emitting diode pixels.

2. The display panel of claim 1, wherein the multiplexer comprises a first transistor and a second transistor, wherein a first source/drain of the first transistor and a first source/drain of the second transistor are electrically connected to a first bonding pad and a second bonding pad respectively, and a second source/drain of the first transistor and a second source/drain of the second transistor are both electrically connected to the one of the plurality of first data lines.

3. The display panel of claim 2, wherein a first gate of the first transistor and a second gate of the second transistor are electrically connected to a first gate control line and a second gate control line respectively.

4. The display panel of claim 2, wherein the first transistor comprises a plurality of first semiconductor structures separated from each other, wherein a first gate of the first transistor, the first source/drain of the first transistor, and the second source/drain of the first transistor overlap the plurality of first semiconductor structures, and the first source/drain of the first transistor extends from above the plurality of first semiconductor structures to the first bonding pad; and wherein the second transistor comprises a plurality of second semiconductor structures separated from each other, wherein a second gate of the second transistor, the first source/drain of the second transistor, and the second source/drain of the second transistor overlap the plurality of second semiconductor structures, and the first source/drain of the second transistor extends from above the plurality of second semiconductor structures to the second bonding pad.

5. The display panel of claim 1, further comprising:
a second data line located above the light-emitting diode display region and not overlapping the liquid crystal display region, the second data line being electrically connected to corresponding ones of the plurality of light-emitting diode pixels.

6. The display panel of claim 1, further comprising:
a first gate driver circuit located above the light-emitting diode display region; and
a first scan line extending along a second direction, and electrically connecting the first gate driver circuit to another at least one of the plurality of light-emitting diode pixels, wherein the first direction is substantially perpendicular to the second direction.

7. The display panel of claim 6, further comprising:
a second scan line, electrically connecting the first gate driver circuit to multiple ones of the plurality of liquid crystal pixels arranged along the second direction, wherein the multiple ones of the plurality of liquid crystal pixels arranged along the second direction and the another at least one of the plurality of light-emitting diode pixels are arranged along the second direction.

8. The display panel of claim 6, further comprising:
a second gate driver circuit located above the light-emitting diode display region; and
a third scan line extending along the second direction, and electrically connecting the second gate driver circuit to multiple ones of the plurality of light-emitting diode pixels arranged along the second direction, wherein a length of the third scan line is greater than a length of the second scan line.

9. The display panel of claim 1, wherein the light-emitting diode display region is located on three sides of the liquid crystal display region.

10. The display panel of claim 1, wherein the one of the plurality of first data lines comprises:
a first conductive line portion connected to the at least one of the plurality of light-emitting diode pixels;
a second conductive line portion connected to the corresponding ones of the plurality of liquid crystal pixels; and
a transition portion connecting the first conductive line portion to the second conductive line portion, wherein an extending direction of the transition portion is different from an extending direction of the first conductive line portion and an extending direction of the second conductive line portion.

11. The display panel of claim 1, further comprising:
a first bonding pad and a second bonding pad located above the substrate and electrically connected to the multiplexer;
a chip on film package structure bonded to the first bonding pad and the second bonding pad, and comprising:
a circuit board;
a light-emitting diode pixel driver circuit located on the circuit board, and electrically connected to the multiplexer through the circuit board and the first bonding pad; and
a liquid crystal pixel driver circuit located on the circuit board, and electrically connected to the multiplexer through the circuit board and the second bonding pad, wherein the multiplexer is configured to cause the one of the plurality of first data lines to switch between receiving a signal output from the light-emitting diode pixel driver circuit and receiving a signal output from the liquid crystal pixel driver circuit.

12. The display panel of claim 1, wherein the one of the plurality of first data lines and another one of the plurality of first data lines adjacent thereto have a first pitch above the light-emitting diode display region, and the one of the plurality of first data lines and the another one of the plurality of first data lines adjacent thereto have a second pitch above the liquid crystal display region, wherein the second pitch is different from the first pitch.

13. (canceled)

14. A spliced display device, comprising:
a plurality of display panels as described in claim 1 spliced together.

15. The spliced display device of claim 14, wherein the multiplexer of each of the plurality of display panels comprises a first transistor and a second transistor, wherein a first source/drain of the first transistor and a first source/drain of the second transistor are electrically connected to a first bonding pad and a second bonding pad respectively, and a second source/drain of the first transistor and a second source/drain of the second transistor are both electrically connected to the one of the plurality of first data lines.

16. The spliced display device of claim 14, wherein each of the plurality of display panels further comprises:
a second data line, located above the light-emitting diode display region and not overlapping the liquid crystal display region, the second data line electrically connected to corresponding ones of the plurality of light-emitting diode pixels.

17. The spliced display device of claim 14, wherein each of the plurality of display panels further comprises:
a first gate driver circuit located above the light-emitting diode display region; and
a first scan line, extending along a second direction, and electrically connecting the first gate driver circuit to another at least one of the plurality of light-emitting diode pixels, wherein the first direction is substantially perpendicular to the second direction.

18. The spliced display device of claim 14, wherein each of the plurality of display panels further comprises:
a first bonding pad and a second bonding pad located above the substrate, and electrically connected to the multiplexer;
a chip on film package structure bonded to the first bonding pad and the second bonding pad, and comprising:
a circuit board;
a light-emitting diode pixel driver circuit located on the circuit board, and electrically connected to the multiplexer through the circuit board and the first bonding pad; and
a liquid crystal pixel driver circuit located on the circuit board, and electrically connected to the multiplexer through the circuit board and the second bonding pad, wherein the multiplexer is configured to switch the one of the plurality of first data lines between receiving a signal output from the light-emitting diode pixel driver circuit and receiving a signal output from the liquid crystal pixel driver circuit.

19. A display panel, comprising:
a substrate comprising a liquid crystal display region and a light-emitting diode display region, wherein the light-emitting diode display region is located on at least one side of the liquid crystal display region;
a plurality of liquid crystal pixels arrayed above the liquid crystal display region;
a plurality of light-emitting diode pixels arrayed above the light-emitting diode display region;
a plurality of first data lines located above the substrate and extending from above the light-emitting diode display region to above the liquid crystal display region, wherein one of the plurality of first data lines is electrically connected to corresponding ones of the liquid crystal pixels and at least one of the light-emitting diode pixels, wherein the corresponding ones of the plurality of liquid crystal pixels and the at least one of the plurality of light-emitting diode pixels are arranged along a first direction; and
a multiplexer located above the substrate and connected to the one of the plurality of first data lines, wherein the multiplexer comprises a first transistor and a second transistor, a first source/drain of the first transistor and a first source/drain of the second transistor are electrically connected to a first bonding pad and a second bonding pad respectively, and a second source/drain of the first transistor and a second source/drain of the second transistor are both electrically connected to the one of the plurality of first data lines.

20. A display panel, comprising:
a substrate comprising a liquid crystal display region and a light-emitting diode display region, wherein the light-emitting diode display region is located on at least one side of the liquid crystal display region;
a plurality of liquid crystal pixels arrayed above the liquid crystal display region;
a plurality of light-emitting diode pixels arrayed above the light-emitting diode display region;
a plurality of first data lines located above the substrate and extending from above the light-emitting diode display region to above the liquid crystal display region, wherein one of the plurality of first data lines is electrically connected to corresponding ones of the liquid crystal pixels and at least one of the light-emitting diode pixels, wherein the corresponding ones of the plurality of liquid crystal pixels and the at least one of the plurality of light-emitting diode pixels are arranged along a first direction; and
a multiplexer located above the substrate and connected to the one of the plurality of first data lines, wherein the one of the plurality of first data lines and another one of the plurality of first data lines adjacent thereto have a first pitch above the light-emitting diode display region, the one of the plurality of first data lines and the another one of the plurality of first data lines adjacent thereto have a second pitch above the liquid crystal display region, and the second pitch is different from the first pitch.
